(19) United States
(12) Patent Application Publication
(10) Pub. No.: US 2025/0342342 A1
(43) Pub. Date: Nov. 6, 2025

(54) PERFORMANCE ESTIMATION METHOD, AND TRAINING METHOD

(71) Applicant: Gigaphoton Inc., Tochigi (JP)

(72) Inventors: Jacob Peter STROCK, Beaverton, OR (US); Levi JORDAN, Beaverton, OR (US)

(73) Assignee: Gigaphoton Inc., Tochigi (JP)

(21) Appl. No.: 19/264,416

(22) Filed: Jul. 9, 2025

Related U.S. Application Data
(63) Continuation of application No. PCT/JP2023/045669, filed on Dec. 20, 2023.
(60) Provisional application No. 63/484,912, filed on Feb. 14, 2023.

(51) Int. Cl. G06N 3/044; H01S 5/00

(52) U.S. Cl. CPC G06N 3/044; H01S 5/0021; H01S 5/0035

(57) ABSTRACT

A performance estimation method for estimating performance of a laser device including a chamber and a pair of electrodes arranged in the chamber includes acquiring a target feature including at least one of a gas pressure in the chamber and an application voltage between the electrodes, and a component replacement scenario including a replacement component and a replacement timing; acquiring a trained recurrent neural network model corresponding to the target feature; acquiring past data of the laser device corresponding to the recurrent neural network model; creating data of a number of used pulses of the replacement component in future based on the component replacement scenario; estimating, by the recurrent neural network model, performance of the target feature in the component replacement scenario based on the past data and the data of the number of used pulses of the replacement component in future; and outputting a result of the estimation.

### CROSS-REFERENCE TO RELATED APPLICATIONS

The present application is a continuation application of International Application No. PCT/JP2023/045669, filed on Dec. 20, 2023, with the priority of U.S. Patent Application No. 63/484,912, filed on Feb. 14, 2023, the entire contents of which are hereby incorporated by reference.

### BACKGROUND

### 1. Technical Field

The present disclosure relates to a performance estimation method and a training method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: US Patent Application Publication No. 2021/0333788
Patent Document 2: US Patent Application Publication No. 2021/0117931
Patent Document 3: Japanese Patent Application Publication No. 2021-177223

### SUMMARY

A performance estimation method, according to an aspect of the present disclosure, for estimating performance of a laser device including a chamber into which a laser gas is introduced and a pair of electrodes arranged in the chamber includes acquiring a target feature including at least one of a gas pressure in the chamber of the laser device and an application voltage between the electrodes, and a component replacement scenario including a replacement component and a replacement timing; acquiring a trained recurrent neural network model corresponding to the target feature; acquiring of past data the laser device corresponding to the recurrent neural network model; creating data of a number of used pulses of the replacement component in future based on the component replacement scenario; estimating, by the recurrent neural network model, performance of the target feature in the component replacement scenario based on the past data and the data of the number of used pulses of the replacement component in future; and outputting a result of the estimation.

A training method, according to another aspect of the present disclosure, of a recurrent neural network model for estimating performance of a first laser device including a chamber into which a laser gas is introduced and a pair of electrodes arranged in the chamber includes acquiring a target feature including at least one of a gas pressure in the chamber of the first laser device and an application voltage between the electrodes, a replacement component, and past plurality of features; extracting an additional feature used for estimation of the target feature among the plurality of features; creating training data including data of before and after replacement of the replacement component, the data including the target feature, a number of used pulses of the replacement component, and the additional feature; and training the recurrent neural network model by the training data.

A training method, according to another aspect of the present disclosure, of a recurrent neural network model for estimating performance of a first laser device including a first chamber into which a laser gas is introduced and a pair of first electrodes arranged in the first chamber includes acquiring a target feature including at least one of a gas pressure in a second chamber of a second laser device and an application voltage between a pair of second electrodes, a replacement component, and past data of a plurality of features, the second laser device being different from the first laser device and including the second chamber into which a laser gas is introduced and the second electrodes arranged in the second chamber; extracting an additional feature used for estimation of the target feature among the plurality of features; creating training data including data of before and after replacement of the replacement component, the data including the target feature, a number of used pulses of the replacement component, and the additional feature; and training the recurrent neural network model by the training data.

### BRIEF DESCRIPTION OF THE DRAWINGS

Embodiments of the present disclosure will be described below merely as examples with reference to the accompanying drawings.

FIG. 1 is a view showing the configuration of an exemplary laser device for an exposure apparatus.

FIG. 2 is a diagram showing the configuration of an exemplary light source management system.

FIG. 3 shows the configuration of the light source management system according to a first embodiment.

FIG. 4 is a block diagram showing functions of a laser performance simulator.

FIG. 5 is a diagram showing flow of a process of creating training data.

FIG. 6 is a table showing specific examples of a target feature, a replacement component, and an additional feature.

FIG. 7 is a diagram showing an example of the configuration of an RNN model.

FIG. 8 is a table showing an example of data input to the RNN model.

FIG. 9 is a diagram showing flow of processing of estimating future performance of the target feature.

FIG. 10 is a table showing specific examples of the target feature and a component replacement scenario.

FIG. 11 is a table showing specific examples of the target feature and the component replacement scenario.

FIG. 12 is a diagram showing an output example of an estimation result.

FIG. 13 is a diagram showing an output example of the estimation result.

FIG. 14 is a diagram showing an output example of the estimation result.

FIG. 15 is a table showing specific examples of the target feature and the component replacement scenario according to a modification.

FIG. 16 is a diagram showing an output example of the estimation result when the target feature and the component replacement scenario shown in FIG. 15 are used.

FIG. 17 is a block diagram showing functions of the laser performance simulator according to a second embodiment.

FIG. 18 is a diagram showing flow of processing of creating training data.

FIG. 19 is a diagram showing flow of processing performed by an RNN model training unit.

FIG. 20 is a diagram showing the configuration of the laser device for the exposure apparatus according to a third embodiment.

FIG. 21 is a block diagram showing functions of the laser performance simulator according to the third embodiment.

FIG. 22 is a diagram showing flow of processing of creating training data.

FIG. 23 is a diagram showing flow of processing of estimating future performance of the target feature.

### DESCRIPTION OF EMBODIMENTS

### Contents

1. Description of terms
2. Device according to comparative example
   2.1 Laser device
      2.1.1 Configuration
   2.1.2 Operation
   2.2 Light source management system
      2.2.1 Configuration
      2.2.2 Operation
3. Problem
4. First embodiment
   4.1 Configuration
      4.1.1 Light source management system
      4.1.2 Laser performance simulator
   4.2 Operation
      4.2.1 RNN model
      4.2.2 Creation of training data
      4.2.3 Training of RNN model
      4.2.4 Performance estimation of target feature
      4.2.5 Output example
   4.3 Effect
   4.4 Modification
5. Second embodiment
   5.1 Configuration
   5.2 Operation
      5.2.1 Creation of training data
      5.2.2 Training of RNN model
   5.3 Effect
6. Third embodiment
   6.1 Laser device
      6.1.1 Configuration
      6.1.2 Operation
   6.2 Laser performance simulator
      6.2.1 Configuration
      6.2.2 Operation
         6.2.2.1 Creation of training data
         6.2.2.2 Training of RNN model
         6.2.2.3 Performance estimation of target feature
   6.3 Effect
7. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Terms

Terms used in the present specification are defined as follows.

A “feature” is a quantifiable feature of a laser device. Examples of the feature include a pulse energy of pulse laser light output from the laser device, a center wavelength, a spectral line width, a gas pressure in a chamber, an application voltage between electrodes, and a number of used pulses of respective components.

A “target feature” is a feature to be estimated by a recurrent neural network model (RNN). The “target feature” is also referred to as an outcome variable, a response variable, or a dependent variable. The “target feature” is input from an external apparatus. An “additional feature” is a feature selected by a feature selection algorithm, such as the random forest algorithm, to perform estimation on the target feature.

A “component replacement scenario” is data configured of a replacement component that is a component to be replaced during a simulation estimation period and a replacement timing that is a timing at which the replacement component is to be replaced, and includes a laser identification number. The “component replacement scenario” is input from the external apparatus.

“Weights” are two different types of weights: a model weight and a sample weight. The model weight is a parameter of the RNN model and is adjusted so that the difference between an estimation value and actual data becomes small during training. The sample weight is a scaling factor associated with each time step of the training data and verification data. The scaling factor is calculated according to a weighting scheme to increase the estimation accuracy associated with component replacement. Mathematically, the scaling factor is applied to a loss term of the optimization algorithm.

A “weighting scheme” is an algorithm that assigns the sample weight. The algorithm generates an unequal weight such that, for example, in the first step of performing component replacement, the weight is set higher to improve the estimation accuracy of the component replacement.

“Training data” is data used for training the RNN model. The training data includes data of the target feature, a number of used pulses of the replacement component, and an additional feature, and a subset of four arrays of the sample weight.

“Verification data” is data used to compare the effectiveness of a trained RNN model. The “verification data” includes data of the target feature, the number of used pulses of the replacement component, and the additional feature, and a subset of four arrays of the sample weight. The “verification data” is data older than the “training data”. The “verification data” is data of a period shorter than the period of the “training data”.

“Hyperparameters” include, for example, a number of hidden layers, a number of hidden neurons, model weight initialization, a learning rate, a learning rate attenuation parameter, and a momentum parameter.

### 2. Device According to Comparative Example

### 2.1 Laser Device

### 2.1.1 Configuration

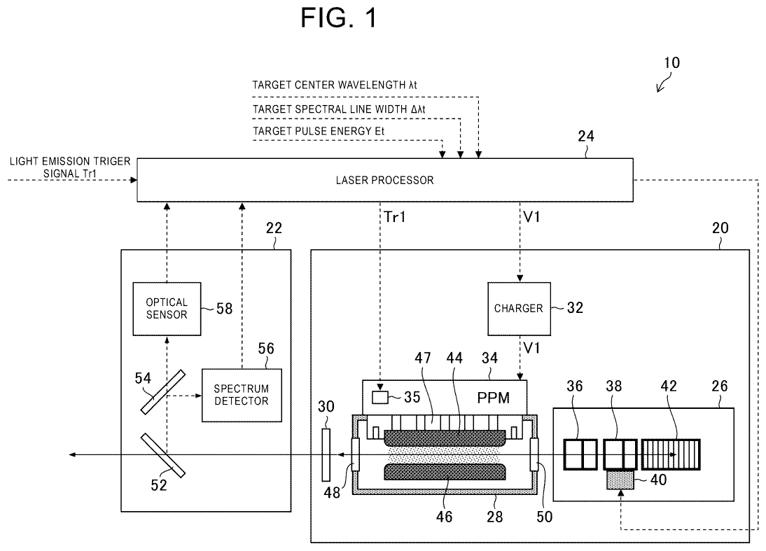

FIG. 1 shows the configuration of a laser device 10 according to a comparative example. The comparative example of the present disclosure is an example recognized by the applicant as known only by the applicant, and is not a publicly known example admitted by the applicant.

The laser device 10 is, for example, an excimer laser device, and includes an oscillator (OSC) 20, a monitor module 22, and a laser processor 24.

The OSC 20 includes a line narrowing module (LNM) 26, a chamber 28, an output coupler (OC) 30, a charger 32, and a pulse power module (PPM) 34. The PPM 34 includes a switch 35.

The LNM 26 includes a first prism 36, a second prism 38, a rotation stage 40 that rotates the second prism 38, and a grating 42. The LNM 26 changes an incident angle on the grating 42 by rotating the second prism 38 so that a center wavelength of pulse laser light is controlled. The rotation stage 40 may be a rotation stage including a piezoelectric element.

The chamber 28 includes a pair of electrodes 44, 46, an insulating member 47, and two windows 48, 50 through which laser light is transmitted. An excimer laser gas is introduced into the chamber 28. The excimer laser gas includes, for example, a rare gas (an Ar gas or a Kr gas), a halogen gas (an F₂ gas), and a buffer gas (an Ne gas). The PPM 34 is connected to the electrode 44 via a feedthrough in the insulating member 47.

The OC 30 is a partial reflection mirror that reflects a part of the pulse laser light and transmits the other part.

The LNM 26 and the OC 30 may configure an optical resonator, and the chamber 28 may be arranged on the optical path of the optical resonator.

The monitor module 22 includes a first beam splitter 52, a second beam splitter 54, a spectrum detector 56 that measures a wavelength and a spectral line width of the pulse laser light, and an optical sensor 58 that detects a pulse energy of the pulse laser light. The spectrum detector 56 may be an etalon spectrometer. The optical sensor 58 may be a photodiode.

### 2.1.2 Operation

The laser processor 24 receives a target center wavelength At, a target spectral line width Δλt, and a target pulse energy Et from an exposure apparatus (not shown). The laser processor 24 sets a charge voltage V1 of the charger 32 so that the pulse laser light having the target pulse energy Et can be obtained.

A charging capacitor (not shown) in the PPM 34 is charged with the charge voltage V1.

Upon receiving a light emission trigger signal Tr1 from the exposure apparatus, the laser processor 24 transmits the light emission trigger signal Tr1 to the switch 35 in the PPM 34. When the switch 35 is operated, charges charged in the charging capacitor are converted into high voltage pulses in the PPM 28 in accordance with the charge voltage VI and applied between the electrodes 44, 46 in the chamber 28.

As a result, discharge occurs between the electrodes 44, 46, and the excimer laser gas in the chamber 28 is excited. Then, the pulse laser light line-narrowed by the optical resonator configured of the OC 30 and the LNM 26 to an ultraviolet wavelength of 150 to 380 nm is output from the OSC 20. The wavelength of the pulse laser light may be an oscillation wavelength of the ArF excimer laser or an oscillation wavelength of the KrF excimer laser. The pulse laser light output from the OSC 20 enters the monitor module 22.

A part of the pulse laser light entering the monitor module 22 is reflected by the first beam splitter 52, and a part of the reflected pulse laser light is further reflected by the second beam splitter 54 to enter the spectrum detector 56. Further, the pulse laser light transmitted through the second beam splitter 54 enters the optical sensor 58.

The spectrum detector 56 measures the center wavelength and the spectral line width of the pulse laser light. The optical sensor 58 measures the pulse energy of the pulse laser light.

The laser processor 24 may control the rotation stage 40 in the LNM 26 so that the center wavelength measured by the spectrum detector 56 becomes the target center wavelength At.

The laser processor 24 may control the charge voltage V1 output from the charger 32 so that the pulse energy measured by the optical sensor 58 becomes the target pulse energy Et.

### 2.2 Light Source Management System

### 2.2.1 Configuration

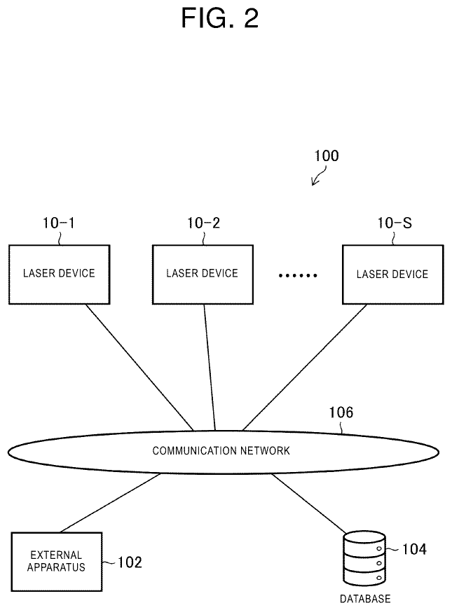

FIG. 2 shows the configuration of a light source management system 100 according to the comparative example. The light source management system 100 includes a plurality of laser devices 10-1, 10-2, . . . , 10-S that output pulse laser light, an external apparatus 102, and a database 104.

The plurality of laser devices 10-1, 10-2, . . . , 10-S may be all laser devices in a semiconductor factory. The laser device may be an excimer laser device. Each of the plurality of laser devices 10-1, 10-2, . . . , 10-S has a unique laser identification number.

The external apparatus 102 may be a personal computer (PC), a display device such as a liquid crystal display (LCD) or an organic electroluminescent display, or an input device such as a keyboard or an audio input device.

The database 104 may be arranged in the semiconductor factory or in the laser device.

The plurality of laser devices 10-1, 10-2, . . . , 10-S, the external apparatus 102, and the database 104 are connected to each other via a communication network 106.

The communication network 106 is a communication network capable of transmitting information by wired or wireless communication or a combination thereof. The communication network 106 may be a wide area network or a local area network.

### 2.2.2 Operation

Data from the plurality of laser devices 10-1, 10-2, . . . , 10-S is continuously stored in the database 104 in association with a total number of oscillation pulses of each of the laser devices and the date and time. The data includes, for example, the gas pressure in the chamber 28, the charge voltage V1, and the number of used pulses of the LNM 26. Further, the data may include the application voltage between the electrodes 44, 46, the number of used pulses of the chamber 28, the number of used pulses of the OC 30, the pulse energy, the spectral line width, the center wavelength, a pulse energy stability, and a partial pressure of the halogen gas in the chamber 28.

The data in the database 104 may be accessed from the external apparatus 102 via the communication network 106.

### 3. Problem

A field service engineer accesses the database 104 using the external apparatus 102 and examines the data in the database 104 to determine a component to be replaced. However, the deterioration speed of each component varies, and features of the laser device are also affected by the state of other components. Therefore, the lifetime of a component is not determined simply by the number of used pulses. Accordingly, the field service engineer uses his experience to estimate the following.
a. Transition of features of the laser device in the future according to the number of pulses or the date and time (performance)
b. Performance of the laser device after component replacement in the future

However, the above estimation is difficult even for an experienced field service engineer.

An object of the present disclosure is to quantitatively estimate performance of the laser device in the future including after component replacement.

### 4. First Embodiment

### 4.1 Configuration

### 4.1.1 Light Source Management System

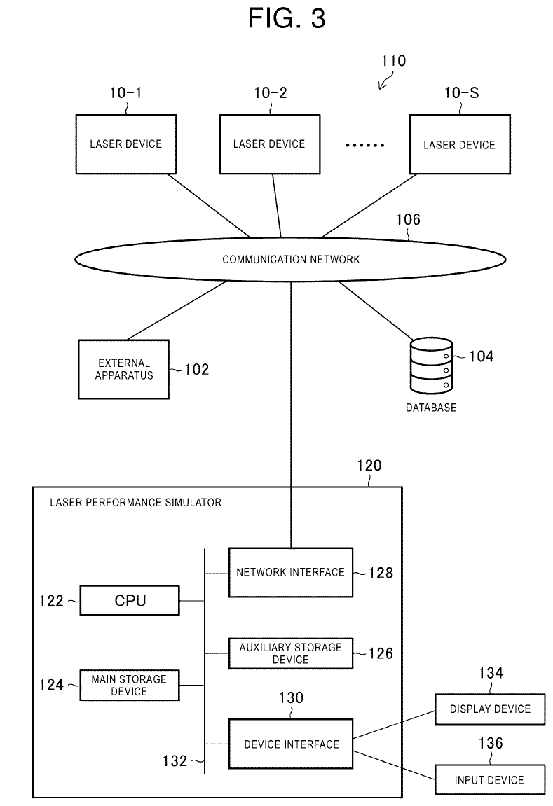

FIG. 3 shows the configuration of a light source management system 110 according to a first embodiment. The light source management system 110 is different from the light source management system 100 in including a laser performance simulator 120. A computer is applied to the laser performance simulator 120. The computer may be in the form of a server, a PC, or a workstation.

The laser performance simulator 120 is connected to the plurality of laser devices 10-1, 10-2, . . . , 10-S, the external apparatus 102, and the database 104 via the communication network 106.

The laser performance simulator 120 includes a central processing unit (CPU) 122, a main storage device 124, an auxiliary storage device 126, a network interface 128, and a device interface 130. The CPU 122, the main storage device 124, the auxiliary storage device 126, the network interface 128, and the device interface 130 are connected to each other via a bus 132. Each of the CPU 122, the main storage device 124, the auxiliary storage device 126, the network interface 128, and the device interface 130 may be plurally provided.

The main storage device 124 is a storage device accessible directly from the CPU 122. The main storage device 124 temporarily stores programs and various types of data. The main storage device 124 may be a volatile memory or a non-volatile memory.

The auxiliary storage device 126 is a storage device inaccessible directly from the CPU 122. The auxiliary storage device 126 permanently stores programs and various types of data. The auxiliary storage device 126 may be a hard disk drive (HDD), a solid state drive (SSD), or a universal serial bus (USB) memory.

The network interface 128 is an interface for connecting to the communication network 106 by wired or wireless communication or a combination thereof.

The device interface 130 is an interface for connecting to a display device 134 and an input device 136.

The laser performance simulator 120 may be included in the external apparatus 102.

### 4.1.2 Laser Performance Simulator

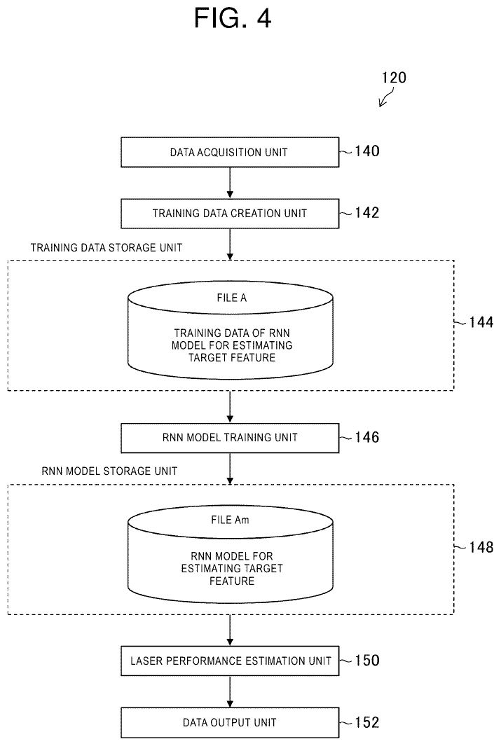

FIG. 4 is a block diagram showing functions of the laser performance simulator 120. The laser performance simulator 120 includes a data acquisition unit 140, a training data creation unit 142, a training data storage unit 144, an RNN model training unit 146, an RNN model storage unit 148, a laser performance estimation unit 150, and a data output unit 152.

The training data creation unit 142 is a unit that creates training data to be used for training an RNN model.

The training data storage unit 144 includes a storage unit that stores a file A for storing the training data.

The RNN model training unit 146 is a processing unit that trains the RNN model by machine learning using the training data.

The RNN model storage unit 148 includes a storage unit that stores a file Am for storing the trained RNN model trained by the RNN model training unit 146.

The storage unit of the training data storage unit 144 and the storage unit of the RNN model storage unit 148 are configured by using the auxiliary storage device 126. The storage unit of the training data storage unit 144 and the storage unit of the RNN model storage unit 148 may be configured using different auxiliary storage devices 126, or may be configured as a part of a storage area in one or a plurality of auxiliary storage devices 126.

The laser performance estimation unit 150 is a processing unit that estimates performance of the laser device 10 using the trained RNN model stored in the file Am.

The data output unit 152 is a processing unit that outputs an estimation result of the laser performance estimation unit 150.

The laser performance simulator 120 shown in FIG. 4 includes the RNN model training unit 146 and the laser performance estimation unit 150, but the configuration of the laser performance simulator 120 is not limited to this example. For example, a laser performance simulator that includes the RNN model training unit 146 to train the RNN model and a laser performance simulator that includes the laser performance estimation unit 150 to estimate the performance of the laser device 10 may be different devices. The laser performance simulator including the RNN model training unit 146 and the laser performance simulator including the laser performance estimation unit 150 may be arranged in different factories, respectively.

### 4.2 Operation

### 4.2.1 RNN Model

The RNN model for performing quantitative estimation on the following is stored in the auxiliary storage device 126.
a. Performance of the laser device in the future
b. Performance of the laser device after component replacement in the future

The RNN model is a neural network model designed to process sequences of data. In other words, the laser performance simulator 120 can accept an input sequence and train the RNN model to generate an output sequence of estimation.

The RNN model has a multi-head structure that takes in a plurality of inputs and can process sequences of past and future data.

In addition, the RNN model has an encoder-decoder structure capable of compressing the input sequence into the output sequence having a different length. That is, the length of the past data sequence used for estimation is not required to match the length of the future data sequence.

The numbers of layers, neurons, and hyperparameters of the RNN model are determined through training of the RNN model.

4.2.2 Creation of training data

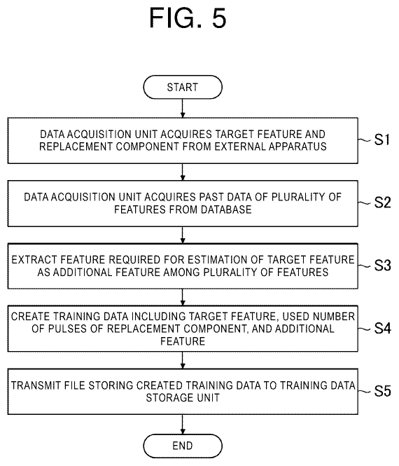

FIG. 5 shows flow of processing of creating training data.

First, in step S1, the data acquisition unit 140 acquires, from the external apparatus, a target feature that is a feature whose performance in the future is estimated by the trained RNN model and a replacement component. The external apparatus may be the external apparatus 102 connected to the communication network 106 or an external apparatus such as the input device 136 connected to the device interface 130 of the laser performance simulator 120.

In step S2, the data acquisition unit 140 further acquires, from the database 104, past data of a plurality of features continuously recorded in association with the total number of oscillation pulses and the date and time, which are past data of a laser device 10T. The laser device 10T is an example of the “second laser device” of the present disclosure. The laser device 10T may be a laser device of any of the plurality of laser devices 10-1, 10-2, . . . , 10-S. The past data includes data before and after replacement of the replacement component. The data acquisition unit 140 may acquire the past data of the plurality of features from the laser device 10T.

The data acquisition unit 140 transmits, to the training data creation unit 142, the target feature and the replacement component acquired in step S1 and the past data of the plurality of features acquired in step S2.

Next, in step S3, the training data creation unit 142 extracts, as an additional feature, a feature required for estimation of the target feature from among the plurality of features of the received past data. For this extraction, the training data creation unit 142 calculates importance of each of the plurality of features. The importance is calculated using, for example, the random forest algorithm. The training data creation unit 142 extracts a feature having a relatively high importance as the additional feature.

Subsequently, in step S4, the training data creation unit 142 creates training data including data of the target feature, the number of used pulses of the replacement component, and the additional feature, and the sample weight. Since the additional feature is different depending on the target feature, the training data is also different depending on the target feature.

Finally, in step S5, the training data creation unit 142 transmits the file A storing the created training data to the training data storage unit 144. The training data storage unit 144 writes the received file A into the storage unit.

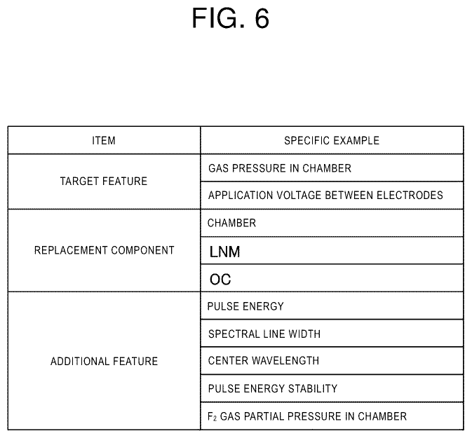

FIG. 6 shows specific examples of the target feature, the replacement component, and the additional feature. Specific examples of the target feature are the gas pressure in the chamber 28 and the application voltage between the electrodes 44, 46. Specific examples of the replacement component are the chamber 28, the LNM 26, and the OC 30. The additional feature is a feature different from the target feature. Specific examples of the additional feature are the pulse energy of the output pulse laser light, the spectral line width, the center wavelength, the pulse energy stability, and the partial pressure of the halogen gas in the chamber 28.

Here, the target feature may include at least one of the gas pressure and the application voltage. The replacement component may include at least one of the chamber 28, the LNM 26, and the OC 30. The additional feature may include at least one of the pulse energy, the spectral line width, the center wavelength, the pulse energy stability, and the partial pressure of the halogen gas.

4.2.3 Training of RNN model

An example of the “training method” of the present disclosure will be described. The RNN model training unit 146 reads the file A storing the training data from the training data storage unit 144, and trains the RNN model using the training data.

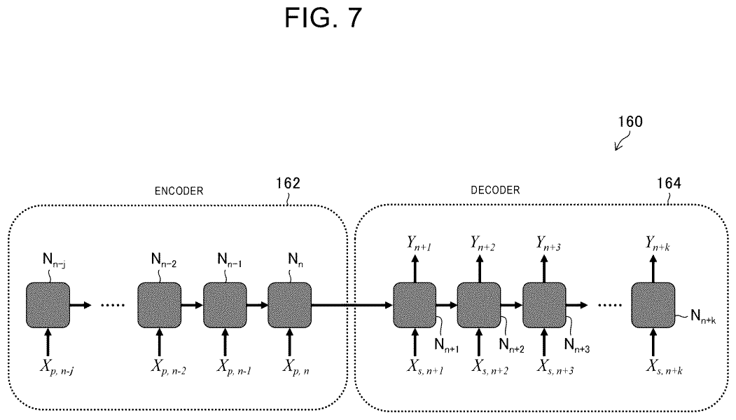

FIG. 7 shows an example of the configuration of an RNN model 160. The RNN model 160 includes an encoder 162 and a decoder 164. In the RNN model 160, an output of the encoder 162 is connected to an input of the decoder 164.

The encoder 162 includes a plurality of neuron layers Nₙ₋ⱼ to Nₙ. The decoder 164 includes a plurality of neuron layers Nₙ₊₁ to Nₙ₊ₓ. A plurality of neurons may exist in each of the neuron layers Nₙ₋ⱼ to Nₙ₊ₖ.

X_{p,n} includes past data of the feature at the number of pulses n. The number of pulses n may be, for example, the total number of oscillation pulses of the laser device 10T. X_{s,n+1} includes past data of the number of used pulses of the replacement component at the number of pulses (n+1). Yₙ₊₁ includes an estimation value of the target feature at the number of pulses (n+1).

Here, the number of pulses increases at a constant increment in each step from (n−j) to (n+k). For example, when the number of pulses n is 20,000 million pulses and the number of pulses increased in each step is 150 million pulses, the number of pulses (n−2) is 19,700 million pulses and the number of pulses (n−1) is 19,850 million pulses. Further, the number of pulses (n+1) is 20, 150 million pulses and the number of pulses (n+2) is 20,300 million pulses.

The training data includes data of a period in which the number of pulses is from (n−j) to (n+k). The RNN model training unit 146 sets a certain number of pulses n in the training data as a step of the start of estimation. For example, the number of pulses n may be set at the time when ⅔ of the entire period of the training data elapses.

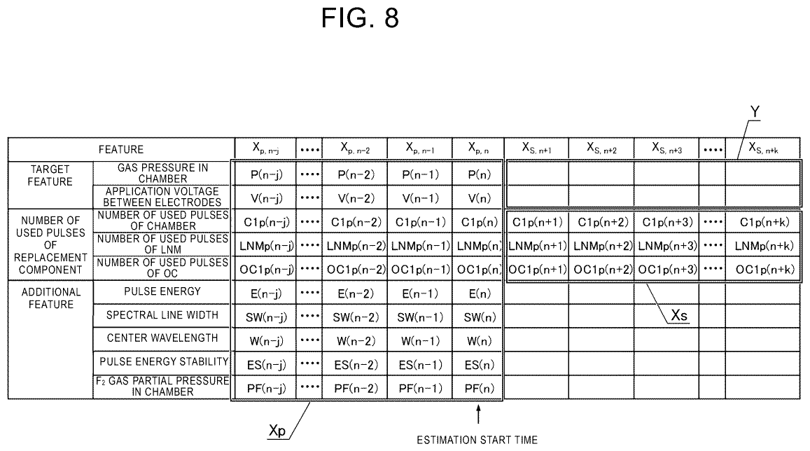

The RNN model training unit 146 inputs, to the neuron layers Nₙ₋ⱼ to Nₙ of the encoder 162 of the RNN model 160, data Xp,ₙ₋ⱼ to X_{p,n} of the target feature, the number of used pulses of the replacement component, and the additional feature in each step from the number of pulses (n−j) to the number of pulses n, which corresponds to the start of estimation. Further, the RNN model training unit 146 inputs, to the neuron layers Nₙ₊₁ to Nₙ₊ₖ of the decoder 164 of the RNN model 160, data X_{s,n+1} to X_{s,n+k} of the number of used pulses of the replacement component in each step from the number of pulses (n+1) to the number of pulses (n+k). For example, when the target feature, the replacement component, and the additional feature are the specific examples shown in FIG. 6, the RNN model training unit 146 inputs Xp and Xs shown in FIG. 8 to the RNN model 160.

That is, the input data X_{p,n-j} to X_{p,n} includes, as the target feature, the gas pressure P(n−j) to P(n) in the chamber 28 and the application voltage V(n−j) to V(n) between the electrodes 44, 46. Further, the input data X_{p,n-j} to X_{p,n} includes, as the number of used pulses of the replacement component, the number of used pulses Clp(n−j) to Clp (n) of the chamber 28, the number of used pulses LNMp(n−j) to LNMp (n) of the LNM 26, and the number of used pulses OClp(n−j) to OClp(n) of the OC 30. Further, the input data X_{p,n-j} to X_{p,n} includes, as the additional feature, the pulse energy E(n−j) to E(n), the spectral line width SW(n−j) to SW(n), the center wavelength W(n−j) to W(n), the pulse energy stability ES(n−j) to ES(n), and the partial pressure PF(n−j) to PF(n) of the halogen gas in the chamber 28.

The input data X_{s,n+1} to X_{s,n+k} includes the number of used pulses Clp(n+1) to Clp(n+k) of the chamber 28, the number of used pulses LNMp(n+1) to LNMp(n+k) of the LNM 26, and the number of used pulses OClp(n+1) to OClp(n+k) of the OC 30.

For these inputs, the RNN model 160 outputs, from the neuron layers Nₙ₊₁ to Nₙ₊ₖ of the decoder 164, estimation values Yₙ₊₁ to Yₙ₊ₖ of the target feature from the number of pulses (n+1) to (n+k). For example, the RNN model 160 outputs Y shown in FIG. 8. That is, the output estimation values Yₙ₊₁ to Yₙ₊ₖ include the gas pressure in the chamber 28 and the application voltage between the electrodes 44, 46.

Then, the RNN model training unit 146 adjusts the model weight of the RNN model 160 which is a scaling factor related to each step of the training data so that the difference between the estimation values Yₙ₊₁ to Yₙ₊ₖ of the target feature and the data of the target feature in the training data in each step from the step having the number of pulses (n+1) to the step having the number of pulses (n+k) becomes small.

As described above, the RNN model training unit 146 adjusts the model weight so that the difference between the estimation value and the true value becomes small by an optimization algorithm such as the stochastic gradient method (SGD), RMSprop, or Adam using the training data.

Further, the RNN model training unit 146 may create the RNN model by comprehensively performing grid search for all combinations of the hyperparameters, or by using the Bayesian optimization algorithm.

The RNN model training unit 146 transmits the file Am storing the trained RNN model 160 to the RNN model storage unit 148. The RNN model storage unit 148 writes the received file Am into the storage unit.

Here, an example in which the RNN model training unit 146 creates a new RNN model has been described, but the RNN model training unit 146 may re-train a trained RNN model to update the model weight.

### 4.2.4 Performance Estimation of Target Feature

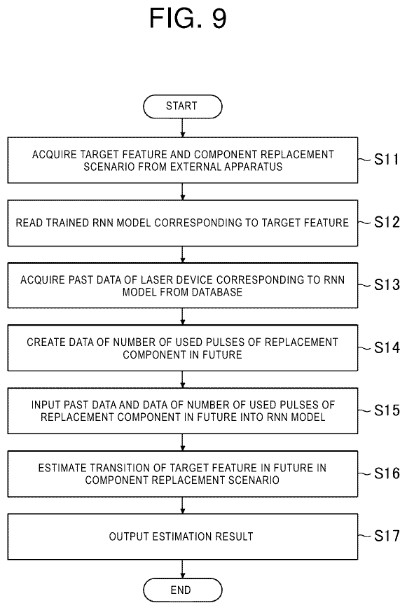

The “performance estimation method” of the present disclosure will be described. FIG. 9 shows flow of processing of estimating performance of the target feature of the laser device in the future. Here, a case in which the replacement timing is the same as the start of estimation will be described.

First, in step S11, the laser performance estimation unit 150 acquires the target feature and the component replacement scenario from an external apparatus. Here, it is assumed that the laser identification number included in the component replacement scenario is an identification number of a laser device 101. The laser device 101 is an example of the “first laser device” in the present disclosure. The laser device 10I may be a laser device of any of the plurality of laser devices 10-1, 10-2, . . . , 10-S. The laser device 10I and the laser device 10T may be devices of the same model, devices of the same configuration, devices of the same application, or devices having the same parameters.

The laser device 101 and the laser device 10T may be devices of different models, devices of different configurations, devices of different applications, or devices having different parameters. Here, the chamber 28 of the laser device 10I is an example of the “first chamber”, and the electrodes 44, 46 of the laser device 101 are an example of the “pair of first electrodes”. Further, the chamber 28 of the laser device 10T is an example of the “second chamber”, and the electrodes 44, 46 of the laser device 10T are an example of the “pair of second electrodes”.

The chamber 28 of the laser device 101 and the chamber 28 of the laser device 10T may be components of the same model or components of different models. The electrodes 44, 46 of the laser device 101 and the electrodes 44, 46 of the laser device 10T may be components of the same model or components of different models.

The replacement timing included in the component replacement scenario may be represented by the total number of oscillation pulses of the laser device 101 or may be represented by the date and time. The external apparatus may be the external apparatus 102 connected to the communication network 106 or the external apparatus such as the input device 136 connected to the device interface 130 of the laser performance simulator 120.

Next, in step S12, the laser performance estimation unit 150 reads, from the RNN model storage unit 148, the file Am storing the trained RNN model for estimating the target feature acquired in step S11, and acquires the RNN model. When the device including the RNN model training unit 146 and the device including the laser performance estimation unit 150 are different devices, the file Am may be distributed from the device including the RNN model training unit 146.

Further, in step S13, the laser performance estimation unit 150 acquires past data of the laser device 10I corresponding to the RNN model acquired in step S12 from the database 104. The past data is associated with the total number of oscillation pulses of the laser device 10I and the date and time. The past data includes data of the target feature, the number of used pulses of the replacement component, and the additional feature. The past data corresponds to Xp of FIG. 8.

In step S14, the laser performance estimation unit 150 creates data of the number of used pulses of the replacement component in each of the steps from the step having the total number of oscillation pulses of the laser device 10I (n+1) to the step having the total number of oscillation pulses (n+k). That is, the laser performance estimation unit 150 calculates the number of used pulses of the replacement component in each step from the data of the number of used pulses of the replacement component when the total number of oscillation pulses is n, which is the start of estimation, and the increased amount of the total number of oscillation pulses of the laser device 101 between the step having the total number of oscillation pulses n and the step having the total number of oscillation pulses (n+k).

At this time, the laser performance estimation unit 150 initializes the number of used pulses to 0 at the replacement timing of the replacement component according to the component replacement scenario. Here, since the replacement timing is the same as the start of estimation, the number of used pulses of the replacement component when the total number of oscillation pulses is n is initialized to 0. The laser performance estimation unit 150 calculates the number of used pulses of the replacement component thereafter based on the increased number of total oscillation pulses of the laser device 101 between the steps. The laser performance estimation unit 150 creates data of the number of used pulses of the replacement component in the future from the calculation result. The number of used pulses of the replacement component corresponds to Xs of FIG. 8.

Subsequently, in step S15, the laser performance estimation unit 150 inputs the past data of the laser device 101 acquired in step S13 and the data of the number of used pulses of the replacement component in the future calculated in step S14 into the RNN model acquired in step S12. In step S16, the RNN model estimates performance of the target feature in the future in accordance with the number of pulses or the date and time in the component replacement scenario. The estimation result corresponds to Y in FIG. 8. The RNN model may further estimate performance of the target feature in the future in a case that component replacement is not performed.

Finally, in step S17, the data output unit 152 outputs the estimation result estimated in step S16. The data output unit 152 may display the estimation result on the display device 134, or may transmit an e-mail or the like via the communication network 106 to notify the external apparatus 102 of the estimation result.

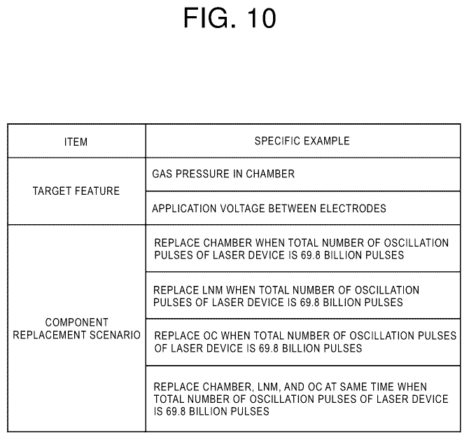

FIG. 10 shows specific examples of the target feature and the component replacement scenario acquired in step S11, where the replacement timing is represented by the total number of oscillation pulses of the laser device 101. In the example shown in FIG. 10, specific examples of the target feature are the gas pressure in the chamber 28 and the application voltage between the electrodes 44, 46. Further, specific examples of the component replacement scenario are four types: a case in which the chamber 28 is replaced when the total number of oscillation pulses of the laser device 10I is 69.8 billion pulses; a case in which the LNM 26 is replaced when the total number of oscillation pulses of the laser device 10I is 69.8 billion pulses; a case in which the OC 30 is replaced when the total number of oscillation pulses of the laser device 10I is 69.8 billion pulses; and a case in which the chamber 28, the LNM 26, and the OC 30 are replaced at the same time when the total number of oscillation pulses of the laser device 10I is 69.8 billion pulses.

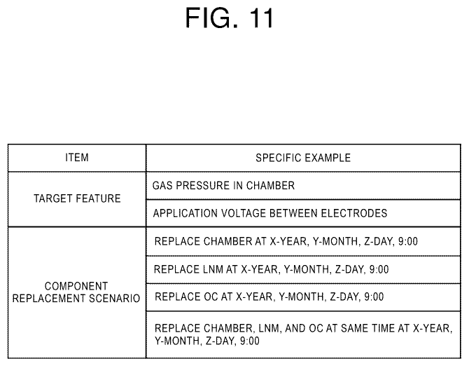

FIG. 11 shows specific examples of the target feature and the component replacement scenario acquired in step $11, where the replacement timing is represented by the date and time. In the example shown in FIG. 11, specific examples of the target feature are the gas pressure in the chamber 28 and the application voltage between the electrodes 44, 46. Further, specific examples of the component replacement scenario are four types: a case in which the chamber 28 is replaced at X-year, Y-month, Z-day, 9:00; a case in which the LNM 26 is replaced at X-year, Y-month, Z-day, 9:00; a case in which the OC 30 is replaced at X-year, Y-month, Z-day, 9:00; and a case in which the chamber 28, the LNM 26, and the OC 30 are replaced at the same time at X-year, Y-month, Z-day, 9:00.

### 4.2.5 Output Example

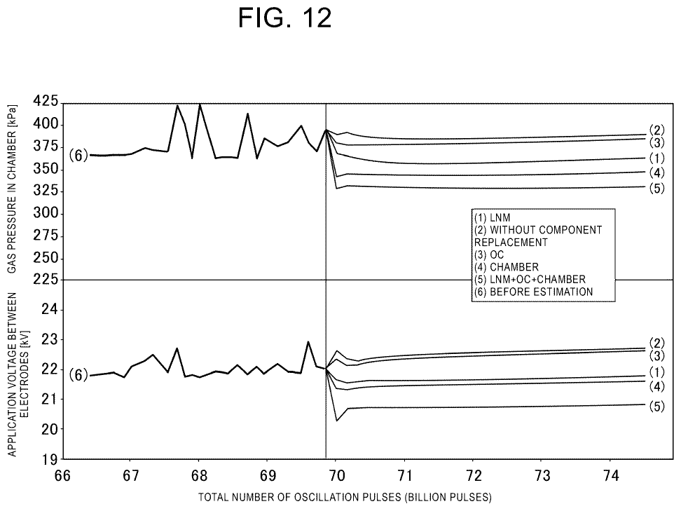

FIG. 12 shows an output example of the estimation result when the target feature and the component replacement scenario shown in FIG. 10 are used. FIG. 12 is a graph in which the horizontal axis represents the total number of oscillation pulses, and the vertical axis represents the value of the target feature. In FIG. 12, past data before estimation and the estimation result after the start of estimation are connected in time series. The past data is data of the target feature until the total number of oscillation pulses of the laser device 10I reaches 69.8 billion pulses, which is the start of estimation. The estimation result is the performance of the target feature in the future after the start of estimation. The estimation result may include the performance of the target feature in the future in each component replacement scenario. The estimation result may include the performance of the target feature in the future in a case that component replacement is not performed. The estimation result may be displayed separately in the upper and lower stages for the respective target features with the horizontal axis being common. In the estimation result, the start of estimation may be indicated by, for example, a line.

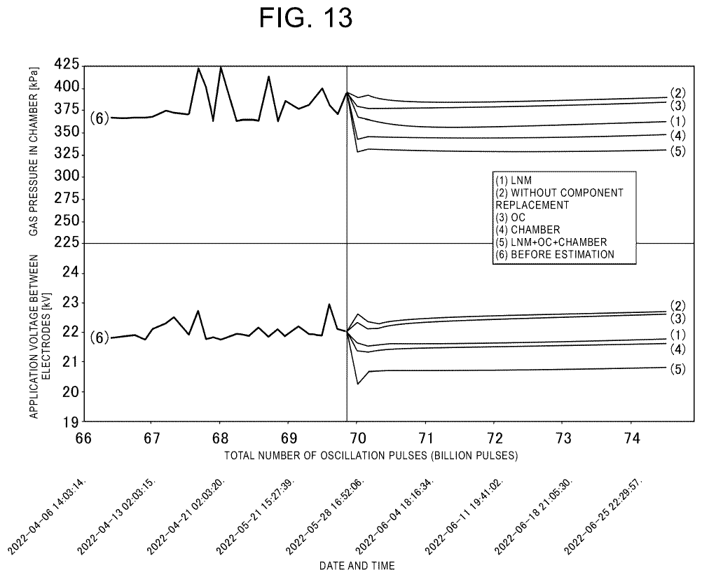

In the graph showing the estimation result, the horizontal axis may be the date and time. As shown in FIG. 13, the horizontal axis may represent both of the total number of oscillation pulses and the date and time. The date and time of the estimation period may be calculated from an average number of oscillation pulses per day calculated from the past data and the total number of oscillation pulses.

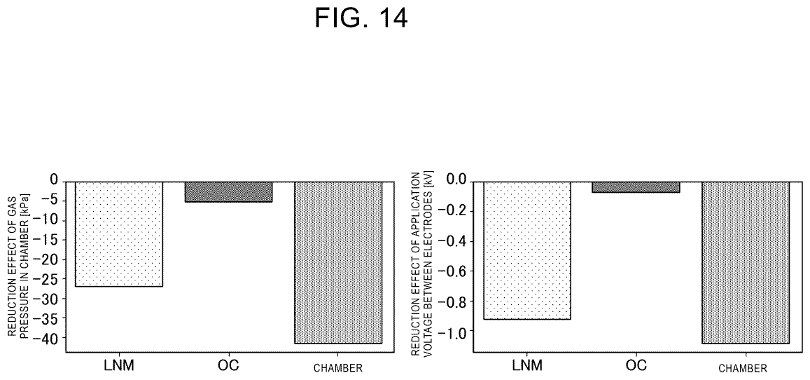

FIG. 14 shows another output example of the estimation result when the target feature and the component replacement scenario shown in FIG. 10 are used. FIG. 14 shows an influence on the target feature as a bar graph in three component replacement scenarios: the LNM 26, the OC 30, and the chamber 28. In FIG. 14, a reduction effect of the gas pressure in the chamber 28 and a reduction effect of the application voltage between the electrodes 44, 46 are displayed separately on the left and right sides as the influence on the target feature. The reduction effects are represented by the difference between the data when the total number of oscillation pulses of the laser device 10I is 69.8 billion pulses and the data when the total number of oscillation pulses is 70.0 billion pulses.

### 4.3 Effect

According to the laser performance simulator 120, quantitative estimation on the following can be performed even by an inexperienced field service engineer.
a. Performance of the laser device in the future
b. Performance of the laser device after component replacement in the future

Further, the field service engineer can estimate future transition of the target feature according to the number of pulses or the date and time in an arbitrary component replacement scenario using the laser performance simulator 120.

Further, the field service engineer can confirm the effect of component replacement in advance based on the estimation result by the laser performance simulator 120.

### 4.4 Modification

Here, a case in which the replacement timing is after the start of estimation, that is, a case in which the replacement timing is in the future from the start of estimation will be described.

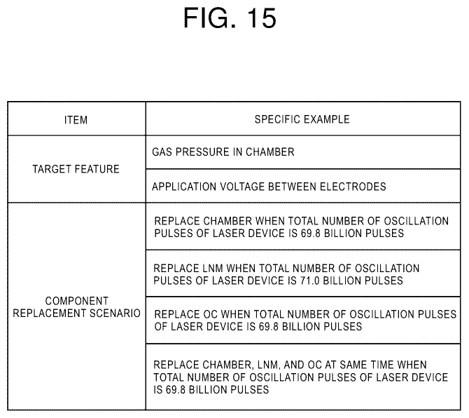

FIG. 15 shows specific examples of the target feature and the component replacement scenario according to a modification. In the example shown in FIG. 15, specific examples of the target feature are the gas pressure in the chamber 28 and the application voltage between the electrodes 44, 46. Further, specific examples of the component replacement scenario are four types: a case in which the chamber 28 is replaced when the total number of oscillation pulses of the laser device 10I is 69.8 billion pulses; a case in which the LNM 26 is replaced when the total number of oscillation pulses of the laser device 10I is 71.0 billion pulses; a case in which the OC 30 is replaced when the total number of oscillation pulses of the laser device 10I is 69.8 billion pulses; and a case in which the chamber 28, the LNM 26, and the OC 30 are replaced at the same time when the total number of oscillation pulses of the laser device 10I is 69.8 billion pulses.

That is, the component replacement scenario shown in FIG. 15 is different from the component replacement scenario shown in FIG. 10 in that the LNM 26 is replaced when the total number of oscillation pulses of the laser device 10I is 71.0 billion pulses.

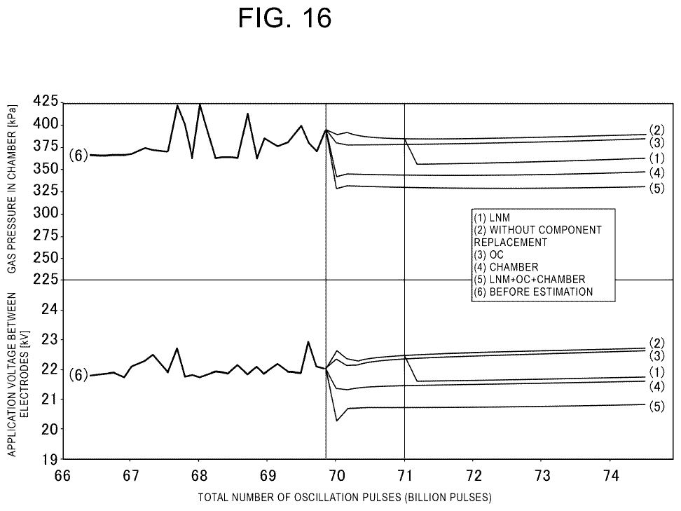

FIG. 16 shows an output example of the estimation result when the target feature and the component replacement scenario shown in FIG. 15 are used. The estimation result of replacement of the LNM 26 in this case is the same as the estimation result in the case of no component replacement from the time when the total number of oscillation pulses is 69.8 billion pulses, which is the start of estimation, to the time when the total number of oscillation pulses is 71.0 billion pulses, which is the replacement timing. Further, after the total number of oscillation pulses is 71.0 billion pulses, the estimation result with the LNM 26 replaced is shown.

When the replacement timing is earlier than the start of estimation, as shown in FIG. 16, the replacement timing after the start of estimation may be displayed by, for example, a line.

As described above, according to the output example according to the modification of the first embodiment, effects similar to those of the output example according to the first embodiment can be obtained. Further, according to the laser performance simulator 120, it is possible to estimate performance of the target feature in the future after the replacement timing even when the replacement timing of the component is after the start of estimation.

### 5. Second embodiment

### 5.1 Configuration

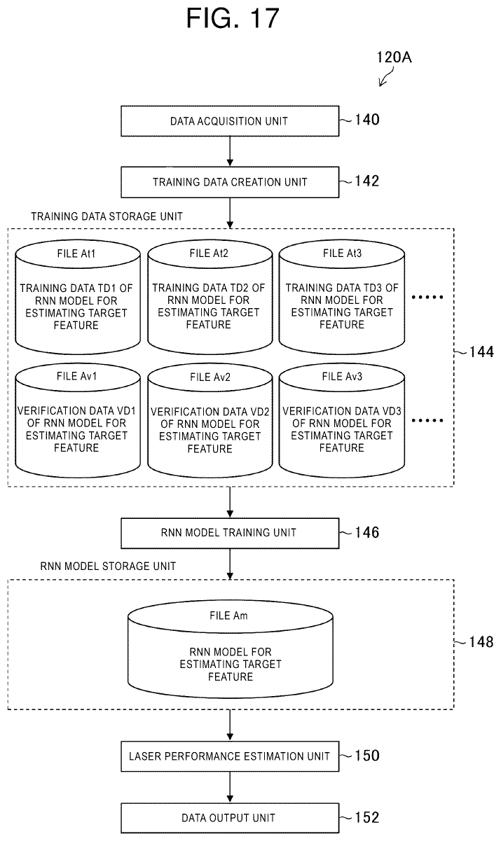

FIG. 17 shows a block diagram showing functions of a laser performance simulator 120A according to a second embodiment. The laser performance simulator 120A is different from the laser performance simulator 120 in the file stored in the training data storage unit 144.

The training data storage unit 144 includes a storage unit that stores a plurality of files At1, At2, At3, . . . for storing plural pieces of training data for training the RNN model for estimating the target feature.

The training data storage unit 144 further includes a storage unit that stores a plurality of files Av1, Av2, Av3, . . . for storing plural pieces of verification data each having the same features as the respective pieces of training data.

### 5.2 Operation

### 5.2.1 Creation of Training Data

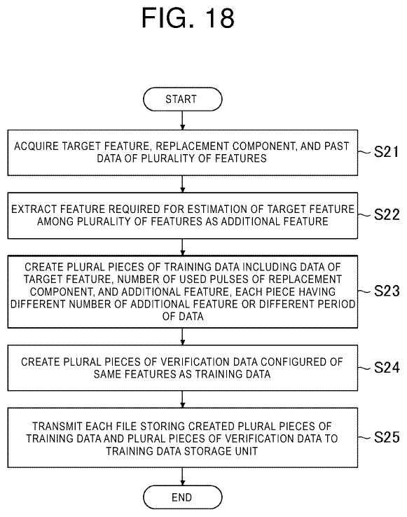

FIG. 18 shows flow of processing of creating training data.

The process of step S21 is similar to step S1 and step S2 of FIG. 5. Further, the process of step S22 is similar to step S3 of FIG. 5.

Subsequently, in step S23, the training data creation unit 142 creates training data including data of the target feature, the number of used pulses of the replacement component, and the additional feature, and the sample weight. At this time, the training data creation unit 142 creates plural pieces of training data each having a different number of additional features or a different period of data. Here, plural pieces of training data each having a different number of additional features and a plurality of pieces of training data each having a different period of data are created. The number of additional features of each piece of training data is, for example, 5, 20, 45, 70. The period of each piece of training data is, for example, 5, 10, 20, 30 billion pulses.

Next, in step S24, the training data creation unit 142 creates plural pieces of verification data that are configured of the same features as the training data. The verification data is data used to compare the estimation accuracy of the trained RNN model. Here, the verification data includes a subset of four arrays, such as the training data. The verification data is data older than the training data. The period of the verification data is shorter than the period of the training data.

Finally, in step S25, the training data creation unit 142 transmits, to the training data storage unit 144, each file storing the created plural pieces of training data and the plural pieces of verification data. For example, a file At1 storing training data TD1 in which the number of additional features is 20, a file At2 storing training data TD2 in which the number of additional features is 45, and a file At3 storing training data TD3 in which the number of additional features is 70 are transmitted to the training data storage unit 144. Further, the training data creation unit 142 transmits, to the training data storage unit 144, a file Av1 storing verification data VD1 configured with the same features as the training data TD1, a file Av2 storing verification data VD2 configured with the same features as the training data TD2, and a file Av3 storing verification data VD3 configured with the same features as the training data TD3.

The training data storage unit 144 writes the plurality of received files into the storage unit.

### 5.2.2 Training of RNN Model

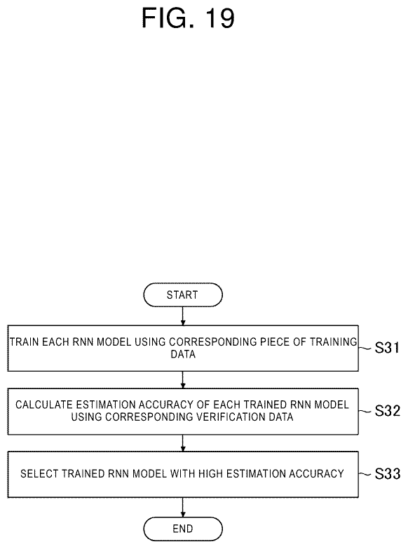

FIG. 19 shows flow of processing performed by the RNN model training unit 146.

First, in step S31, the RNN model training unit 146 reads a file storing training data from the training data storage unit 144, and trains the RNN model using the training data. Since there are plural pieces of training data, a trained RNN model corresponding to each of the training data is created. That is, each RNN model of the plurality of RNN models is trained by the corresponding piece of training data of the plural pieces of training data. For example, the trained RNN model trained by the training data TD1, the trained RNN model trained by the training data TD2, and the trained RNN model trained by the training data TD3 are created.

Next, in step S32, the RNN model training unit 146 calculates the estimation accuracy of each RNN model of the plurality of trained RNN models using the verification data corresponding to each of the training data used for training. For example, the RNN model training unit 146 calculates the estimation accuracy of the trained RNN model trained by the training data TDI using the verification data VD1. Further, the RNN model training unit 146 calculates the estimation accuracy of the trained RNN model trained by the training data TD2 using the verification data VD2. Further, the RNN model training unit 146 calculates the estimation accuracy of the trained RNN model trained by the training data TD3 using the verification data VD3.

Finally, in step S33, the RNN model training unit 146 selects a trained RNN model having a relatively high estimation accuracy. For example, the RNN model training unit 146 selects the trained RNN model trained by the training data TD3 as the RNN model with the highest estimation accuracy. The RNN model training unit 146 transmits the file Am storing the selected RNN model to the RNN model storage unit 148.

In the comparison of the RNN models, the estimation accuracy and the calculation speed may be evaluated. The RNN model may be determined based on the evaluation. Comparisons of model performance and verification data may be used to determine optimal settings for the period of input data and the number of input additional features.

### 5.3 Effect

According to the laser performance simulator 120A, effects similar to those of the laser performance simulator 120 can be obtained.

Further, according to the laser performance simulator 120A, since the RNN model is trained by plural pieces of training data and the trained RNN model with high estimation accuracy is selected, the estimation accuracy can be improved as compared with the laser performance simulator 120.

### 6. Third Embodiment

### 6.1 Laser Device

### 6.1.1 Configuration

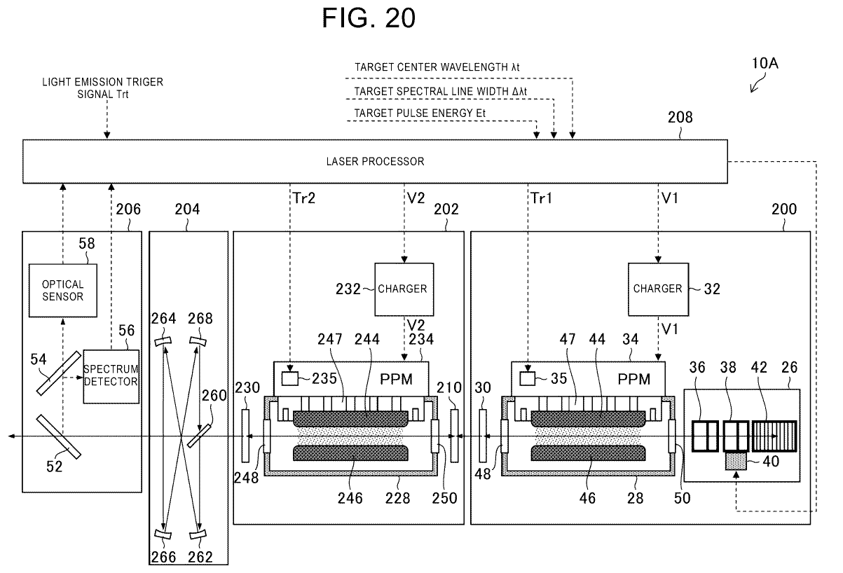

FIG. 20 shows the configuration of a laser device 10A for the exposure apparatus according to a third embodiment. The laser device 10A includes an OSC 200, an amplifier (AMP) 202, an optical pulse stretcher (OPS) 204, a monitor module 206, and a laser processor 208.

The configuration of the OSC 200 is similar to that of the OSC 20.

The AMP 202 includes a rear mirror (RM) 210, a chamber 228, an OC 230, a charger 232, and a PPM 234. The PPM 234 includes a switch 235. The configurations of the chamber 228, the charger 232, and the PPM 234 are similar to those of the corresponding elements of the OSC 200.

The RM 210 is a partial reflection mirror that partially reflects a part of the pulse laser light and transmits the other part. The reflectance of the RM 210 may be between 80% and 90%.

The chamber 228 includes a pair of electrodes 244, 246, an insulating member 247, and two windows 248, 250 through which laser light is transmitted. An excimer laser gas is introduced into the chamber 228.

The OSC 230 is a partial reflection mirror that partially reflects a part of the pulse laser light and transmits the other part. The reflectance of the OSC 230 may be between 10% and 30%.

The RM 210 and the OC 230 may configure an optical resonator, and the chamber 228 may be arranged on the optical path of the optical resonator. The optical resonator may be a Fabry-Perot optical resonator.

The OPS 204 includes a beam splitter (BS) 260, a concave mirror (CM) 262, a CM 264, a CM 266, and a CM 268. The optical path length of the delay optical path of the OPS 204 is, for example, between 2 meters and 14 meters. The reflectance of the BS 260 is, for example, between 40% and 70%. The laser light reflected by the BS 260 may be reflected by the CM 262, the CM 264, the CM 266, the CM 268, and the beam may be focused again on the BS 260.

The configuration of the monitor module 206 is similar to that of the monitor module 22.

### 6.1.2 Operation

The laser processor 208 receives the target center wavelength At, the target spectral line width Δλt, and the target pulse energy Et from the exposure apparatus. The laser processor 208 sets the charge voltage V1 of the charger 32 and a charge voltage V2 of the charger 232 so that the pulse laser light having the target pulse energy Et can be obtained.

The charging capacitor in the PPM 34 is charged with the charge voltage V1, and a charging capacitor (not shown) in the PPM 234 is charged with the charge voltage V2.

Upon receiving a light emission trigger signal Trt from the exposure apparatus, the laser processor 208 transmits the light emission trigger signal Tr1 to the switch 35 in the PPM 34. When the switch 35 is operated, charges charged in the charging capacitor are converted into high voltage pulses in the PPM 34 in accordance with the charge voltage V1 and applied between the electrodes 44, 46 in the chamber 28.

As a result, discharge occurs between the electrodes 44, 46, and the excimer laser gas in the chamber 28 is excited. Then, the light line-narrowed to an ultraviolet wavelength of 150 to 380 nm is output from the OSC 20 as seed light. The wavelength of the seed light may be an oscillation wavelength of the ArF excimer laser or an oscillation wavelength of the KrF excimer laser.

Upon receiving the light emission trigger signal Trt from the exposure apparatus, the laser processor 208 transmits a light emission trigger signal Tr2 to the switch 235 of the PPM 234 so that discharge occurs between the electrodes 244, 246 when the seed light output from the OSC 20 enters the discharge space in the chamber 228 of the AMP 202.

When the switch 235 is operated, charges charged in the charging capacitor (not shown) in the PPM 234 are converted into high voltage pulses in the PPM 234 in accordance with the charge voltage V2 and applied between the electrodes 244, 246 in the chamber 228.

As a result, discharge occurs between the electrodes 244, 246, and the excimer laser gas in the chamber 228 is excited. At this timing, the seed light output from the OSC 20 is transmitted through the RM 210 and enters the discharge space in the chamber 228. The entering seed light is amplified by the optical resonator configured of the OC 230 and the RM 210, and is output from the AMP 202.

The pulse laser light output from the AMP 202 enters the OPS 204.

The pulse laser light having entered the OPS 204 circulates through the delay optical path of the OPS 204, whereby the pulse width is extended.

The pulse laser light having passed through the OPS 204 enters the monitor module 206, and the center wavelength, the spectral line width, and the pulse energy of the pulse laser light are measured.

The laser processor 208 may control the charge voltage V2 output from the charger 232 so that the pulse energy measured by the optical sensor 58 becomes the target pulse energy Et.

### 6.2 Laser Performance Simulator

### 6.2.1 Configuration

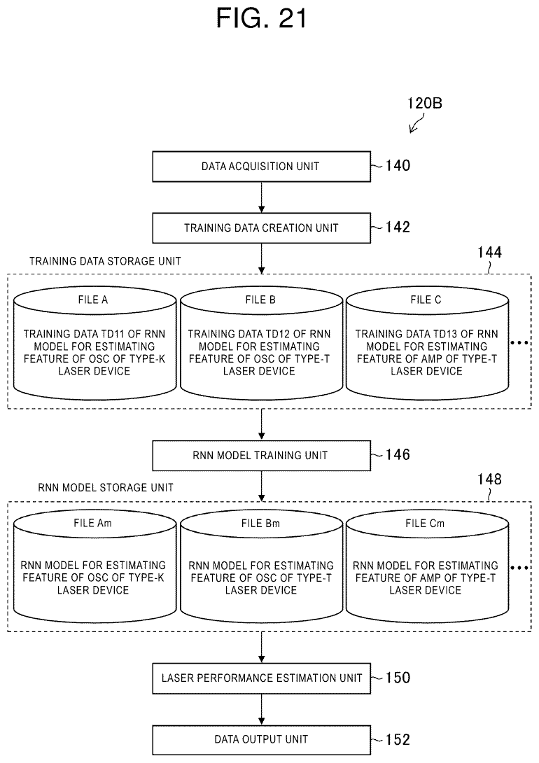

FIG. 21 shows a block diagram showing functions of a laser performance simulator 120B according to the third embodiment. The laser performance simulator is 120B different from the laser performance simulator 120 in the file stored in the training data storage unit 144 and the file stored in the RNN model storage unit 148.

The type of the laser device varies depending on the wavelength of the pulse laser light output from the laser device and the system configuration of the laser device. Here, the laser device 10 configured of one chamber 28 shown in FIG. 1 is represented as a type-K laser device, and the laser device 10A configured of two chambers 28, 228 shown in FIG. 20 is represented as a type-T laser device. Further, the OSCs 20, 200 and the AMP 202 are different modules.

The training data storage unit 144 includes a storage unit that stores files A, B, C, . . . in which different pieces of training data are stored depending on the type of the laser device and the module.

The RNN model storage unit 148 includes a storage unit that stores files Am, Bm, Cm, . . . in which different RNN models trained by the RNN model training unit 146 are stored depending on the type of the laser device and the module.

### 6.2.2 Operation

### 6.2.2.1 Creation of Training Data

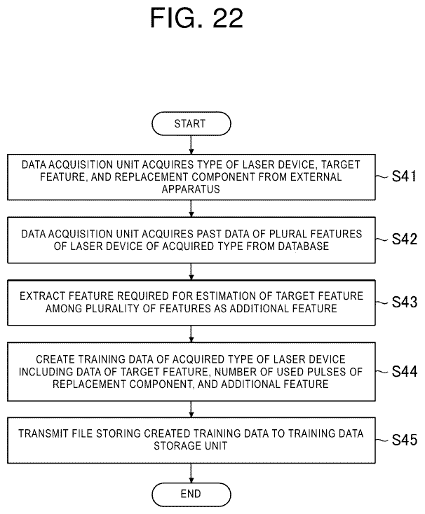

FIG. 22 shows flow of processing of creating training data.

In step S41, the data acquisition unit 140 acquires, from the external apparatus, information of the type of the laser device in addition to the target feature and the replacement component. The information of the type of the laser device includes the model of the laser device, the wavelength of the pulse laser light output from the laser device, the system configuration of the laser device, and the application of the laser device.

The training data creation unit 142 creates different pieces of training data depending on the type of the laser device and the module. Therefore, in step S42, the data acquisition unit 140 acquires, from the database 104, past data of plural features of the laser device of the same type as the type of the laser device acquired in step S41.

The process of step S43 is similar to step S3 of FIG. 5.

Subsequently, in step S44, the training data creation unit 142 creates training data, which is training data of the type of the laser device acquired in step S41, including data of the target feature, the number of used pulses of the replacement component, and the additional feature, and the sample weight. Here, training data TD11 of the RNN model for estimating a feature of the OSC of the type-K laser device as the target feature, training data TD12 of the RNN model for estimating a feature of the OSC of the type-T laser device as the target feature, and training data TD13 of the RNN model for estimating a feature of the AMP of the type-T laser device as the target feature are created.

Finally, in step S45, the training data creation unit 142 transmits the files each storing the corresponding created training data to the training data storage unit 144. Here, the file A storing the training data TD11, the file B storing the training data TD12, and the file C storing the training data TD13 are transmitted to the training data storage unit 144.

The training data storage unit 144 writes the received file A, file B, and file C into the storage unit.

Thus, different pieces of training data are created depending on the type of the laser device. Here, different pieces of training data are created for training of the RNN model for estimating performance of the laser device configured of one chamber and training of the RNN model for estimating performance of the laser device configured of two chambers.

Further, different pieces of training data are created depending on the module. Here, different pieces of training data are created for training of the RNN model for estimating performance using a feature of the OSC as the target feature and training of the RNN model for estimating performance using a feature of the AMP as the target feature.

Different pieces of training data may be created for training of the RNN model for estimating performance when a component configuring the OSC is replaced and training of the RNN model for estimating performance when a component configuring the AMP is replaced.

Different pieces of training data may be created for training of the RNN model for estimating performance of the laser device for outputting pulse laser light having the oscillation wavelength of the ArF excimer laser and training of the RNN model for estimating performance of the laser device for outputting pulse laser light having the oscillation wavelength of the KrF excimer laser.

### 6.2.2.2 Training of RNN Model

The RNN model training unit 146 reads the file storing the training data from the training data storage unit 144, and trains the RNN model. At this time, a trained RNN model corresponding to the training data is created.

For example, the RNN model training unit 146 trains the RNN model for estimating a feature of the OSC of the type-K laser device using the training data TD11. Further, the RNN model training unit 146 trains the RNN model for estimating a feature of the OSC of the type-T laser device using the training data TD12. Further, the RNN model training unit 146 trains the RNN model for estimating a feature of the AMP of the type-T laser device using the training data TD13.

The RNN model training unit 146 transmits files storing the respective trained RNN models to the RNN model storage unit 148. For example, the file Am storing the RNN model for estimating a feature of the OSC of the type-K laser device, the file Bm storing the RNN model for estimating a feature of the OSC of the type-T laser device, and the file Cm storing the RNN model for estimating a feature of the AMP of the type-T laser device are transmitted to the RNN model storage unit 148.

The RNN model storage unit 148 writes the received file Am, file Bm, and file Cm into the storage unit.

### 6.2.2.3 Performance Estimation of Target Feature

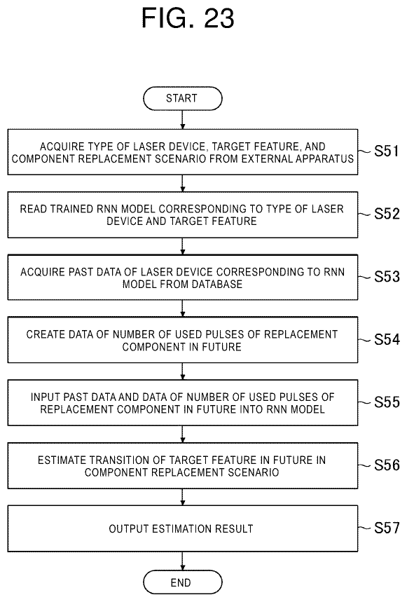

FIG. 23 shows flow of processing of estimating future performance of the target feature.

In step S51, the laser performance estimation unit 150 acquires, from the external apparatus 102, the type of the laser device 10I and the target feature to be estimated, and the component replacement scenario.

Further, in step S52, the laser performance estimation unit 150 reads, from the RNN model storage unit 148, a file storing the trained RNN model for estimating the target feature of the laser device of the acquired type of the laser device 101, and acquires the RNN model. For example, when the acquired type of the laser device 101 is the type-T laser device and the acquired target feature is a feature of the OSC, the RNN model storage unit 148 reads the file Bm storing the RNN model for estimating the feature of the OSC of the type-T laser device.

The processes of steps S53 to S57 are similar to steps S13 to S17 of FIG. 9.

Thus, different trained RNN models are acquired depending on the type of the laser device. Here, the acquired trained RNN model is different between when performance of the laser device configured of one chamber is estimated and when performance of the laser device configured of two chambers is estimated.

Further, different trained RNN models are acquired depending on the module. Here, the acquired trained RNN model is different between when a feature of the OSC feature is the target feature and when a feature of the AMP is the target feature.

Different trained RNN models may be acquired when performance of the laser device for outputting pulse laser light having the oscillation wavelength of the ArF excimer laser is estimated and when performance of the laser device for outputting pulse laser light having the oscillation wavelength of the KrF excimer laser is estimated.

Different trained RNN models may be acquired depending on the replacement component. For example, the acquired trained RNN model may be different between when the replacement component is a component configuring the OSC and when the replacement component is a component configuring the AMP.

### 6.3 Effect

According to the laser performance simulator 120B, effects similar to those of the laser performance simulator 120 can be obtained.

Further, according to the laser performance simulator 120B, since the trained RNN model is created and used differently depending on the type of the laser device and the module, the estimation accuracy can be improved as compared with the laser performance simulator 120.

### 7. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A performance estimation method for estimating performance of a laser device including a chamber into which a laser gas is introduced and a pair of electrodes arranged in the chamber, the performance estimation method comprising:
acquiring a target feature including at least one of a gas pressure in the chamber of the laser device and an application voltage between the electrodes, and a component replacement scenario including a replacement component and a replacement timing;
acquiring a trained recurrent neural network model corresponding to the target feature;
acquiring past data of the laser device corresponding to the recurrent neural network model;
creating data of a number of used pulses of the replacement component in future based on the component replacement scenario;
estimating, by the recurrent neural network model, performance of the target feature in the component replacement scenario based on the past data and the data of the number of used pulses of the replacement component in future; and
outputting a result of the estimation.

2. The performance estimation method according to claim 1,
wherein the replacement timing includes a total number of oscillation pulses of the laser device or date and time.

3. The performance estimation method according to claim 1,
wherein the past data is associated with a total number of oscillation pulses of the laser device.

4. The performance estimation method according to claim 1,
wherein the replacement timing is after start of estimation of the performance.

5. The performance estimation method according to claim 1,
wherein the trained recurrent neural network model to be acquired is different between when the laser device is a laser device that outputs pulse laser light having an oscillation wavelength of an ArF excimer laser and when the laser device is a laser device that outputs pulse laser light having an oscillation wavelength of a KrF excimer laser.

6. The performance estimation method according to claim 1,
wherein the trained recurrent neural network model to be acquired is different between when the laser device includes one chamber being the chamber and when the laser device includes two chambers each being the chamber.

7. The performance estimation method according to claim 1, comprising
acquiring the trained recurrent neural network model different depending on the replacement component.

8. The performance estimation method according to claim 7,
wherein the laser device includes an oscillator and an amplifier, and
the trained recurrent neural network model to be acquired is different between when the replacement component is a component configuring the oscillator and when the replacement component is a component configuring the amplifier.

9. The performance estimation method according to claim 1, comprising
further estimating, by the recurrent neural network model, performance of the target feature in future in a case without replacing the replacement component.

10. The performance estimation method according to claim 1, comprising displaying a graph in which the past data and the result of the estimation are connected,
wherein a vertical axis or a horizontal axis of the graph indicates at least one of a total number of oscillation pulses of the laser device, and date and time.

11. The performance estimation method according to claim 1, comprising displaying the result of the estimation in a graph,
wherein the result of the estimation includes reduction effect of the target feature.

12. A training method of a recurrent neural network model for estimating performance of a first laser device including a chamber into which a laser gas is introduced and a pair of electrodes arranged in the chamber, the training method comprising:
acquiring a target feature including at least one of a gas pressure in the chamber of the first laser device and an application voltage between the electrodes, a replacement component, and past data of a plurality of features;
extracting an additional feature used for estimation of the target feature among the plurality of features;
creating training data including data of before and after replacement of the replacement component, the data including the target feature, a number of used pulses of the replacement component, and the additional feature; and
training the recurrent neural network model by the training data.

13. The training method according to claim 12, comprising:
creating plural pieces of training data each having a different number of the additional features or a different period of data;
creating plural pieces of verification data configured of the same feature as the plural pieces of training data, respectively;
training each of a plurality of recurrent neural network models by a corresponding piece of the plural pieces of training data;
calculating an estimation accuracy of each of the trained recurrent neural network models by a corresponding piece of the plural pieces of verification data; and
selecting the trained recurrent neural network model having the estimation accuracy being relatively high.

14. The training method according to claim 12, comprising:
calculating importance of each of the plurality of features; and
extracting the feature having the importance being relatively high as the additional feature.

15. The training method according to claim 12,
wherein the additional feature includes at least one of a pulse energy, a spectral line width, a center wavelength, and pulse energy stability of output pulse laser light, and a partial pressure of a halogen gas included in the laser gas in the chamber.

16. The training method according to claim 12,
wherein the training data to be created is different between when the first laser device is a laser device that outputs pulse laser light having an oscillation wavelength of an ArF excimer laser and when the first laser device is a laser device that outputs pulse laser light having an oscillation wavelength of a KrF excimer laser.

17. The training method according to claim 12,
wherein the trained data to be created is different between when the first laser device includes one chamber being the chamber and when the first laser device includes two chambers each being the chamber.

18. The training method according to claim 12,
wherein the first laser device includes an oscillator and an amplifier, and
the training data to be created is different between when the replacement component is a component configuring the oscillator and when the replacement component is a component configuring the amplifier.

19. A training method of a recurrent neural network model for estimating performance of a first laser device including a first chamber into which a laser gas is introduced and a pair of first electrodes arranged in the first chamber, the training method comprising:
acquiring a target feature including at least one of a gas pressure in a second chamber of a second laser device and an application voltage between a pair of second electrodes, a replacement component, and past data of a plurality of features, the second laser device being different from the first laser device and including the second chamber into which a laser gas is introduced and the second electrodes arranged in the second chamber;
extracting an additional feature used for estimation of the target feature among the plurality of features;
creating training data including data of before and after replacement of the replacement component, the data including the target feature, a number of used pulses of the replacement component, and the additional feature; and
training the recurrent neural network model by the training data.

20. The training method according to claim 19, comprising:
creating plural pieces of training data each having a different number of the additional features or a different period of data;
creating plural pieces of verification data configured of the same feature as the plural pieces of training data, respectively;
training each of a plurality of recurrent neural network models by a corresponding piece of the plural pieces of training data;
calculating an estimation accuracy of each of the trained recurrent neural network models by a corresponding piece of the plural pieces of verification data; and
selecting the trained recurrent neural network model having the estimation accuracy being relatively high.
